(19) United States
(12) Patent Application Publication
(10) Pub. No.: US 2008/0001209 A1
(43) Pub. Date: Jan. 3, 2008

(54) Non-volatile memory device and method of manufacturing the non-volatile memory device

(76) Inventors: Eun-Suk Cho, Suwon-si (KR); Kyu-Charn Park, Pyeongtaek-si (KR); Jong-Jin Lee, Seongnam-si (KR); Jeong-Dong Choe, Anyang-si (KR)

Correspondence Address: LEE & MORSE, P.C., 3141 FAIRVIEW PARK DRIVE, SUITE 500, FALLS CHURCH, VA, 22042, US

(21) Appl. No.: 11/783,548

(22) Filed: Apr. 10, 2007

(30) Foreign Application Priority Data
Jun. 29, 2006 (KR) 2006-59590

(51) Int. Cl. H01L 29/788; H01L 21/336

(52) U.S. Cl. 257/321; 438/264; 257/E29.304; 257/E21.422

(57) ABSTRACT

A non-volatile memory device may include a substrate having a field region and an active region including a rounded upper edge portion and a flat upper central portion, an effective tunnel oxide layer on the flat upper central portion of the active region, a split floating gate electrode on the effective tunnel oxide layer, the floating gate electrode having a width greater than a width of the effective tunnel oxide layer, a dielectric layer pattern on the floating gate electrode, the dielectric layer pattern including metal oxide, and a control gate electrode on the dielectric layer pattern.

### BACKGROUND OF THE INVENTION

1. Field of the Invention

One or more aspects of the present invention relate to non-volatile memory devices and methods of manufacturing such non-volatile memory devices. More particularly, one or more aspects of the present invention relate to non-volatile memory devices including a dielectric layer that has a high dielectric constant, and methods of manufacturing such non-volatile memory devices.

2. Description of the Related Art

Examples of volatile memory device may include electrically erasable programmable read only memory (EEPROM) devices or flash memory devices capable of rapidly erasing data. Flash memory devices may electrically control an input/output of data using Fowler-Nordheim (F-N) tunneling or channel hot electron injection methods.

A cell transistor of a flash memory device may have a stacked structure that includes a tunnel oxide layer, a floating gate electrode, a dielectric layer and a control gate electrode, which are sequentially stacked.

Generally, flash memory devices may be classified as either a NOR type flash memory device or a NAND type flash memory device. The NOR type flash memory device may include a contact electrically connected to source/drain regions of each of the cell transistors. An electrical signal may be applied to the source/drain regions through the contact to drive the cell transistors. In the NOR type flash memory devices, it may be necessary to have a wide interval in which the contact is formed between the cell transistors. Thus, integration of a NOR type flash memory device may be difficult.

The NAND type flash memory devices may have a string-like structure in which a plurality of cell transistors are connected in series. A string selection transistor and a ground selection transistor may be connected to both ends of the cell transistor having the string structure, respectively. Therefore, the NAND type flash memory device may generally be operated by a unit string that includes 16 unit cells or 32 unit cells. Further, because NAND type flash memory devices do not include a contact connected to source/drain regions of each of the cell transistors, the NAND type flash memory devices may be readily integrated.

In some cases, a non-volatile memory device may have a design rule of no more than about 90 nm. As non-volatile memory devices are becoming highly integrated, intervals between adjacent floating gate electrodes are narrowed. As the intervals between adjacent floating gate electrodes are narrowed, disturbance between the adjacent floating gate electrodes may increase and, as a result of such disturbance, data in the cell transistor may be changed. To suppress the disturbance, it is generally required to reduce a parasite capacitance. Further, to reduce the parasite capacitance, it is generally required to decrease a confronting area between the floating gate electrodes.

However, when the confronting area between the floating gate electrodes is decreased, an effective surface area of a dielectric layer formed on the floating gate electrode is also reduced. When the effective surface area of the dielectric layer is reduced, a voltage may not be sufficiently transmitted to the floating gate electrode from the control gate electrode. As a result, a great amount of the voltage may be lost during transmission between the floating gate electrode and the control gate electrode. That is, the non-volatile memory device may have a low coupling ratio.

Particularly, the coupling ratio R may be represented as following Equation 1.

R=Cdielectric/(Cdielectric+CTO) (Equation 1)

In Equation 1, Cdielectric represents a capacitance of the dielectric layer, and CTO indicates a capacitance of the tunnel oxide layer.

As shown in Equation 1, to increase the coupling ratio, the capacitance of the dielectric layer may be increased and/or the capacitance of the tunnel oxide layer may be decreased.

However, as mentioned above, as the effective surface area of the dielectric layer on the floating gate electrode has been decreased, the capacitance of the dielectric layer is also reduced, thereby decreasing the coupling ratio.

That is, it may be difficult to increase the coupling ratio and decrease the parasitic capacitance between the floating gate electrodes. Therefore, highly integrated non-volatile memory devices that have a desired coupling ratio and a low parasite capacitance are needed.

### SUMMARY OF THE INVENTION

The present invention is therefore directed to non-volatile memory devices and methods of manufacturing such non-volatile memory devices, which substantially overcome one or more of the problems due to the limitations and disadvantages of the related art.

It is therefore a feature of an embodiment of the present invention to provide non-volatile memory devices that have a high coupling ratio and a low parasitic capacitance.

It is therefore a separate feature of an embodiment of the present invention to provide methods of manufacturing non-volatile memory devices that have a high coupling ratio and a low parasitic capacitance.

At least one of the above and other features and advantages of the present invention may be realized by providing a non-volatile memory device, including a substrate having a field region and an active region including a rounded upper edge portion and a flat upper central portion, an effective tunnel oxide layer on the flat upper central portion of the active region, a split floating gate electrode on the effective tunnel oxide layer, the floating gate electrode having a width greater than a width of the effective tunnel oxide layer, a dielectric layer pattern on the floating gate electrode, the dielectric layer pattern including metal oxide, and a control gate electrode on the dielectric layer pattern.

The dielectric layer pattern may be a split dielectric layer pattern having a shape corresponding to a shape of the floating gate electrode. The dielectric layer pattern may be a linear dielectric layer pattern extending on the field region beyond the rounded upper edge portion of the active region.

The dielectric layer pattern may include at least one of tantalum oxide (Ta₂O5), titanium oxide (TiO₂), hafnium oxide (HfO₂), zirconium oxide (ZrO₂), hafnium silicate (HfSiₓO_{y}), zirconium silicate (ZrSiₓO_{y}), hafnium nitride silicate (HfSiₓO_{y}N_{z}), zirconium nitride silicate (ZrSiₓO_{y}N_{z}), aluminum oxide (Al₂O₃), aluminum nitride oxide (AlₓO_{y}N_{z}), hafnium aluminate (HfAlₓO_{y}), yttrium oxide (Y₂O₃), niobium oxide (Nb₂O₅), cesium oxide (CeO₂), indium oxide (InO₃), lanthanum oxide (LaO₂), strontium titanium oxide (SrTiO₃), lead titanium oxide (PbTiO₃), strontium ruthenium oxide (SrRuO₃) and calcium ruthenium oxide (CaRuO₃). These may be used alone or in combination.

The floating gate electrode may include polysilicon. The control gate electrode may include a metal nitride layer pattern. The non-volatile memory device may further include a polysilicon layer pattern on the metal nitride layer pattern. The floating gate electrode may have a thickness of about 150 Å to about 300 Å.

At least one of the above and other features and advantages of the present invention may be separately realized by providing a method of manufacturing a non-volatile memory device, including forming a preliminary gate structure on a substrate, the preliminary gate structure including a preliminary tunnel oxide layer, a preliminary floating gate electrode and a preliminary dielectric layer pattern including metal oxide, which are sequentially stacked, selectively oxidizing surfaces of the substrate at sides of the preliminary gate structure to form an effective tunnel oxide layer including the preliminary tunnel oxide layer, forming trench isolation layers in the substrate at the sides of the preliminary gate structure to define a field region and an active region of the substrate, forming a conductive layer on the preliminary gate structure, and patterning the preliminary floating gate electrode, the preliminary dielectric layer pattern and the conductive layer to form a floating gate electrode, a dielectric layer pattern and a control gate electrode.

The preliminary dielectric layer pattern may include at least one of tantalum oxide (Ta₂O₅), titanium oxide (TiO₂), hafnium oxide (HfO₂), zirconium oxide (ZrO₂), hafnium silicate (HfSiₓO_{y}), zirconium silicate (ZrSiₓO_{y}), hafnium nitride silicate (HfSiₓO_{y}N_{z}), zirconium nitride silicate (ZrSiₓO_{y}N_{z}), aluminum oxide (Al₂O₃), aluminum nitride oxide (AlₓO_{y}N_{z}), hafnium aluminate (HfAlₓO_{y}), yttrium oxide (Y₂O₃), niobium oxide (Nb₂O₅), cesium oxide (CeO₂), indium oxide (InO₃), lanthanum oxide (LaO₂), strontium titanium oxide (SrTiO₃), lead titanium oxide (PbTiO₃), strontium ruthenium oxide (SrRuO₃) and calcium ruthenium oxide (CaRuO₃). These may be used alone or in combination.

Selectively oxidizing surfaces of the substrate at sides of the preliminary gate structure may include selectively oxidizing surfaces of the substrate using a wet oxidation process. The method may further include forming a hard mask pattern on the preliminary dielectric layer pattern, the hard mask pattern being used for patterning the preliminary gate structure and including silicon nitride.

The method may further include forming a spacer including silicon nitride on sidewalls of the preliminary gate structure and the hard mask pattern. Forming the trench isolation layer may include etching the substrate using the preliminary gate structure as an etching mask to form an isolation trench, filling the isolation trench with a preliminary isolation layer, partially removing the preliminary isolation layer until a sidewall of the preliminary dielectric layer pattern is partially exposed to form the trench isolation layer, and removing the hard mask pattern to expose an upper face of the preliminary dielectric layer pattern.

Before forming the preliminary isolation layer, the method may include oxidizing the spacer on the sidewalls of the preliminary gate structure and the hard mask pattern to convert the silicon nitride in the spacer into oxide.

The spacer may be oxidized using a radical oxidation process. Selectively oxidizing surface of the substrate may include selectively oxidizing surfaces of the substrate at opposing sides of the preliminary gate structure.

At least one of the above and other features and advantages of the present invention may be realized by providing a method of manufacturing a non-volatile memory device, forming a preliminary gate structure on a substrate, the preliminary gate structure including a preliminary tunnel oxide layer and a preliminary floating gate electrode sequentially stacked, selectively oxidizing surfaces of the substrate at both sides of the preliminary gate structure to form an effective tunnel oxide layer including the preliminary tunnel oxide layer, forming trench isolation layers in the substrate at the both sides of the preliminary gate structure to define a field region and an active region of the substrate, the active region having a flat upper central portion on which the effective tunnel oxide layer is positioned, sequentially forming a dielectric layer including metal oxide and a control gate layer on the preliminary gate structure, and patterning the preliminary floating gate electrode, the dielectric layer and the control gate layer to form a split floating gate electrode, a dielectric layer pattern and a control gate electrode.

The method may further include sequentially forming a buffer oxide layer pattern and a hard mask pattern on the preliminary dielectric layer pattern, the buffer oxide layer pattern and hard mask pattern being used for patterning the preliminary gate structure.

Forming the trench isolation layer may include etching the substrate using the preliminary gate structure as an etching mask to form an isolation trench, filling the isolation trench with a preliminary isolation layer, partially removing the preliminary isolation layer to form the trench isolation layer, the trench isolation layer having an upper surface that is positioned on a plane on which an upper surface of the preliminary floating gate electrode is placed, and removing the hard mask pattern and the buffer oxide layer pattern to expose an upper face of the preliminary floating gate electrode.

### BRIEF DESCRIPTION OF THE DRAWINGS

The above and other features and advantages of the invention will become more apparent to those of ordinary skill in the art by describing in detail exemplary embodiments thereof with reference to the attached drawings, in which:

FIG. 1 illustrates a perspective view of an exemplary embodiment of a non-volatile memory device employing one or more aspects of the present invention;

FIG. 2 illustrates a cross-sectional view of the exemplary non-volatile memory device illustrated in FIG. 1, taken along a line I-I′ of FIG. 1;

FIGS. 3 to 11 illustrate cross-sectional views of stages in a method of manufacturing the exemplary non-volatile memory device illustrated in FIGS. 1 and 2;

FIG. 12 illustrates a perspective view of a second exemplary embodiment of a non-volatile memory device employing one or more aspects of the present invention;

FIG. 13 illustrates a cross-sectional view of the second exemplary embodiment of the non-volatile memory device illustrated in FIG. 12, taken along a line II-II′ in FIG. 12; and

FIGS. 14 to 20 illustrate cross-sectional views of stages in a method of manufacturing the non-volatile memory device illustrated in FIGS. 12 and 13.

### DETAILED DESCRIPTION OF THE INVENTION

Korean Patent Application No. 2006-59590 filed on Jun. 29, 2006, in the Korean Intellectual Property Office, and entitled: “Non-Volatile Memory Device and Method of Manufacturing the Non-Volatile Memory Device,” is incorporated by reference herein in its entirety.

Aspects of the present invention are described below with reference to the accompanying drawings, in which exemplary embodiments of the invention are shown. Aspects of the invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

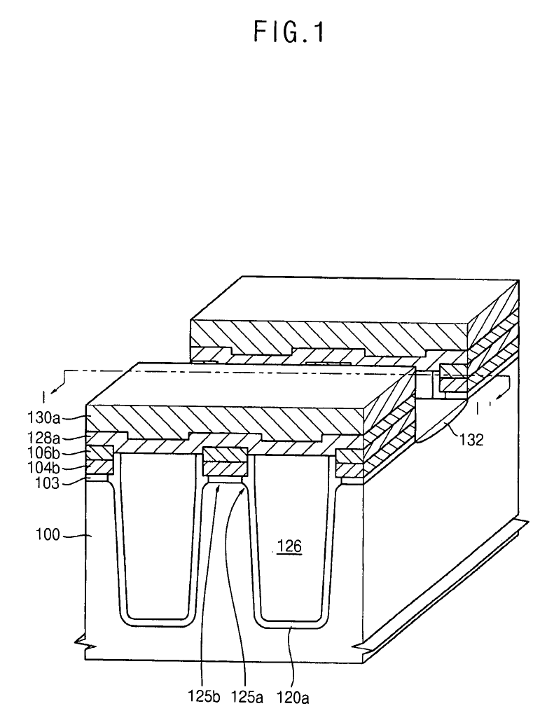

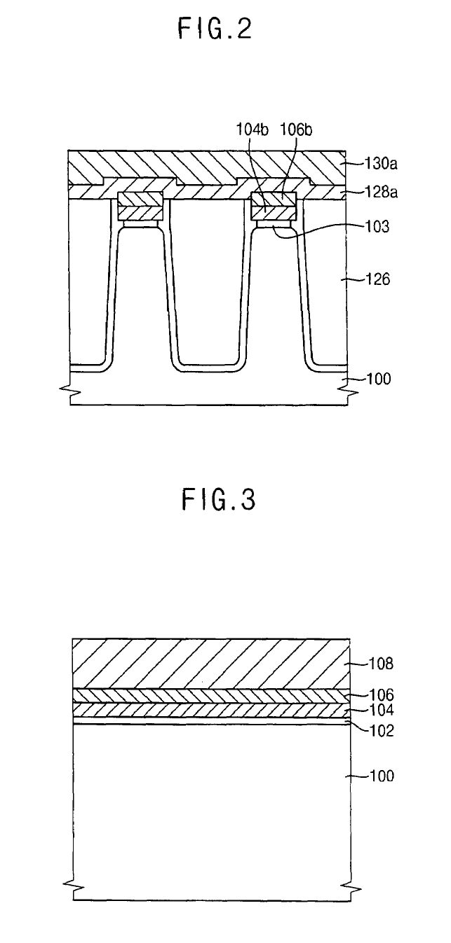

FIG. 1 illustrates a perspective view of an exemplary embodiment of a non-volatile memory device employing one or more aspects of the present invention, and FIG. 2 illustrates a cross-sectional view of the exemplary non-volatile memory device illustrated in FIG. 1, taken along a line I-I′ of FIG. 1.

The exemplary non-volatile memory device illustrated in FIG. 1 is a NAND type flash memory device, but embodiments of the invention need not be limited thereto. The non-volatile memory device may be formed on a semiconductor substrate 100. The semiconductor substrate 100 may include single crystalline silicon.

Isolation layers 126 may be formed in the semiconductor substrate 100 and may define an active region and a field region of the semiconductor substrate 100. The isolation layers 126 may be formed by, e.g., a shallow trench isolation (STI) process.

The active region and the field region may have substantially linear shapes extending along a first direction traversing the semiconductor substrate 100. The active region may have a rounded upper edge portion 125a and a flat upper central portion 125b.

An effective tunnel oxide layer 103 may be formed on the flat upper central portion 125b of the active region. A relatively thick oxide layer 120a may be formed on the rounded upper edge portion 125a of the active region. The thick oxide layer 120a may not function as the effective tunnel oxide layer 103. Thus, the effective tunnel oxide layer 103 may have a relatively small effective area.

As the area of the effective tunnel oxide layer 103 is decreased, the effective tunnel oxide layer 103 may have a reduced capacitance. Therefore, such non-volatile memory devices employing one or more aspects of the invention may have an improved coupling ratio, which may positively influence and improve programming and erasing operations thereof.

A floating gate electrode 104b may be formed on the effective tunnel oxide layer 103. The floating gate electrode 104b may correspond to a split floating gate electrode. The floating gate electrode 104b may have a width greater than that of the flat upper central portion 125b of the active region. The floating gate electrode 104b may include polysilicon for keeping or discharging electrons.

When the floating gate electrode 104b has a thickness of less than about 150 ∈, the floating gate electrode 104b may have poor electron retention characteristics and/or patterning the floating gate electrode 104b may be very difficult. In contrast, when the floating gate electrode 104b has a thickness greater than about 300 Å, a parasitic capacitance between the adjacent floating gate electrodes 104b may be increased. Thus, the floating gate electrode 104b may have a thickness of about 150 Å to about 300 Å.

Moreover, when the parasitic capacitance between the adjacent floating gate electrodes 104b is increased due to a large thickness of the floating gate electrode 104b, disturbance between adjacent cells may be generated. When the disturbance between the adjacent cells is high, e.g., above a predetermined amount, a threshold voltage of a respective cell transistor may be changed due to data in an adjacent cell. More particularly, an interval between the floating gate electrodes 104b may be narrowed proportional to a reduction of a design rule for implementing the non-volatile memory device so that failures of the non-volatile memory device due to disturbance may be remarkably augmented, e.g., increased.

However, according to one or more aspects of the invention, the floating gate electrode 104b may have a thickness that is relatively thinner than a floating gate electrode of a conventional non-volatile memory device. Thus, embodiments of the invention enable disturbance, which may negatively impact performance of the nonvolatile memory device(s), to be reduced by, e.g., reducing a thickness of the floating gate electrode. For example, in the exemplary embodiment illustrated in FIG. 1, the floating gate electrode 104b may have a thickness of about 150 Å to about 300Å.

A split dielectric layer pattern 106b may be formed on the floating gate electrode 104b. The dielectric layer pattern 106b may include metal oxide having a high dielectric constant equal to or greater than about 10.

Examples of the dielectric layer pattern 106b may include, e.g., tantalum oxide (Ta₂O₅), titanium oxide (TiO₂), hafnium oxide (HfO₂), zirconium oxide (ZrO₂), hafnium silicate (HfSiₓO_{y}), zirconium silicate (ZrSiₓO_{y}), hafnium nitride silicate (HfSiₓO_{y}N_{z}), zirconium nitride silicate (ZrSiₓO_{y}N_{z}), aluminum oxide (Al₂O₃), aluminum nitride oxide (AlₓO_{y}N_{z}), hafnium aluminate (HfAlₓO_{y}), yttrium oxide (Y₂O₃), niobium oxide (Nb₂O₅), cesium oxide (CeO₂), indium oxide (InO₃), lanthanum oxide (LaO₂), strontium titanium oxide (SrTiO₃), lead titanium oxide (PbTiO₃), strontium ruthenium oxide (SrRuO₃), calcium ruthenium oxide (CaRuO₃), etc. These may be used alone or in combination.

When the dielectric layer pattern 106b has a thickness of less than about 100 Å, a leakage current through the dielectric layer pattern 106 may be increased. In contrast, when the dielectric layer pattern 106b has a thickness of above about 300 Å, the dielectric layer pattern 106b may have a low capacitance. Thus, in some embodiments of the invention, the dielectric layer pattern 106b may have a thickness of about 100 Å to about 300 Å.

In the exemplary embodiment illustrated in FIG. 1, the dielectric layer pattern 106b may include a metal oxide having a high dielectric constant and thus, the dielectric layer pattern 106 may have a high capacitance. A coupling ratio of the non-volatile memory device may be improved by increasing the capacitance of the dielectric layer pattern 106b, and increasing the coupling ratio of the non-volatile memory device may positively impact and improve the programming and erasing operations.

In some embodiments of the invention, the dielectric layer pattern 106 may have a split shape by unit cells so that the disturbance caused by the parasitic capacitance between the adjacent cells may be suppressed.

A control gate electrode 128a may be formed on the dielectric layer pattern 106b. The control gate electrode 128a may have a substantially linear shape extending along a second direction substantially perpendicular to the first direction.

The control gate electrode 128a may include a metal nitride layer pattern having a high work function, e.g., a work function of about 4.6 eV to about 5.2 eV. The metal nitride layer pattern may include, e.g., tantalum nitride, titanium nitride, etc. These can be used alone or in a combination thereof.

When a metal nitride layer pattern having a high work function is used for the control gate electrode 128a, an energy barrier between the control gate electrode 128a and the dielectric layer pattern 106b may be higher. Thus, the backward transmission of electrons from the control gate electrode 128a to the dielectric layer pattern 106b may be decreased.

In some embodiments of the invention, the metal nitride layer pattern may have a thickness of about 20 Å to about 1,000 Å. More particularly, e.g., in some embodiments of the invention, the metal nitride layer pattern may have a thickness of about 100 Å to about 300 Å.

A polysilicon layer pattern 130a may be formed on the control gate electrode 128a including, e.g., the metal nitride layer pattern. In cases in which the polysilicon layer pattern 130a has a thickness of more than about 500 Å, disturbance between adjacent polysilicon layer patterns 130a may be generated. Thus, in some embodiments of the invention, the polysilicon layer pattern 130a may have a thickness of no more than about 500 Å.

In cases in which metal oxide is used for the dielectric layer pattern 106b, it may be difficult to use polysilicon as a material of the control gate electrode 128a due to a Fermi-level pinning effect. More particularly, when the polysilicon layer is formed on the dielectric layer pattern 106b including the metal oxide, the polysilicon layer on the metal oxide layer may have a work function lower than that of a polysilicon layer on a silicon oxide layer. Further, the work function of the polysilicon layer on the metal oxide layer may not be readily controlled due to impurities in the metal oxide layer. Therefore, in some embodiments of the invention, the control gate electrode 128a including metal nitride may be formed on the dielectric layer pattern 106b.

Source/drain regions 132 may be formed in the semiconductor substrate 100 between the control gate electrodes 128a.

In the exemplary embodiment illustrated in FIG. 1, a dielectric layer pattern having a high dielectric constant is used in the exemplary non-volatile memory device. Further, an area of the effective tunnel oxide layer is decreased. Thus, the coupling ratio may be sufficiently increased. Furthermore, the disturbance caused by the parasitic capacitance between the adjacent floating gate electrodes may be suppressed. As a result, a window margin with respect to programming and erasing data may be increased so that multi-leveled operations for writing and reading a plurality of data in a single cell may be readily carried out.

An exemplary method of manufacturing the non-volatile memory device illustrated in FIGS. 1 and 2 will be described below.

FIGS. 3 to 11 illustrate cross-sectional views illustrating stages in a method of manufacturing the exemplary non-volatile memory device illustrated in FIGS. 1 and 2.

Referring to FIG. 3, a preliminary tunnel oxide layer 102, a floating gate layer 104, a dielectric layer 106 and a hard mask layer 108 may be sequentially formed on the semiconductor substrate 100, e.g., single crystalline silicon substrate.

The preliminary tunnel oxide layer 102 may be formed by, e.g., thermally oxidizing the semiconductor substrate 100.

Polysilicon for keeping and discharging electrons may be deposited on the preliminary tunnel oxide layer 102 to form the floating gate layer 104. The floating gate layer 104 may have a thickness substantially the same as that of the floating gate electrode 104b to be formed therefrom.

When the floating gate layer 104 has a thickness of less than about 150 Å, the floating gate layer 104 may have poor electron-retention characteristics and/or patterning the floating gate layer 104 may be very difficult. In contrast, when the floating gate layer 104 has a thickness of above about 300 Å, a parasitic capacitance between the adjacent floating gate electrodes may be increased. Thus, in some embodiments of the invention, the floating gate layer 104 may have a thickness of about 150 Å to about 300 Å.

Metal oxide having a high dielectric constant of at least about 10 may be deposited on the floating gate layer 104 to form the dielectric layer 106.

Examples of the dielectric layer 106 may include, e.g., tantalum oxide (Ta₂O₅), titanium oxide (TiO₂), hafnium oxide (HfO₂), zirconium oxide (ZrO₂), hafnium silicate (HfSiₓO_{y}), zirconium silicate (ZrSiₓO_{y}), hafnium nitride silicate (HfSiₓO_{y}N_{z}), zirconium nitride silicate (ZrSiₓO_{y}N_{z}), aluminum oxide (Al₂O₃), aluminum nitride oxide (AlₓO_{y}N_{z}), hafnium aluminate (HfAlₓO_{y}), yttrium oxide (Y₂O₃), niobium oxide (Nb₂O₅), cesium oxide (CeO₂), indium oxide (InO₃), lanthanum oxide (LaO₂), strontium titanium oxide (SrTiO₃), lead titanium oxide (PbTiO₃), strontium ruthenium oxide (SrRuO₃), calcium ruthenium oxide (CaRuO₃), etc. These may be used alone or in combination.

More particularly, e.g., a hafnium oxide layer or a hafnium aluminate layer having a dielectric constant of about twenty (20) may be used for the dielectric layer 106. In some embodiments of the invention, the hafnium oxide layer and the hafnium aluminate layer may be formed by, e.g., a chemical vapor deposition (CVD) process, an atomic layer deposition (ALD) process, etc.

Silicon nitride may be deposited on the dielectric layer 106 by, e.g., a CVD process to form the hard mask layer 108.

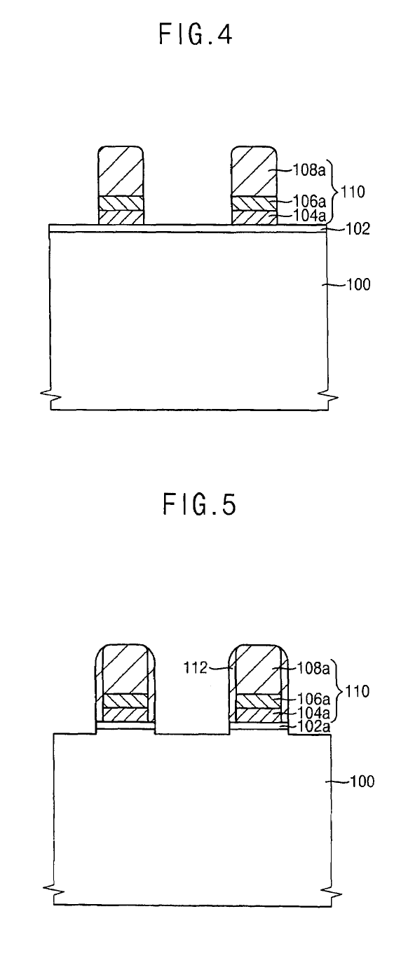

Referring to FIG. 4, the hard mask layer 108 may be patterned by, e.g., a photolithography using a photoresist pattern (not shown) process to form a hard mask pattern 108a. The photoresist pattern may then be removed by, e.g., an ashing process and/or a stripping process.

The dielectric layer 106 and the floating gate layer 104 may be etched using the hard mask pattern 108a as an etching mask to form a preliminary dielectric layer pattern 106a and a preliminary floating gate electrode 104a, respectively.

After the etching process is completed, a linear preliminary gate structure 110 including the preliminary floating gate electrode 104a, the preliminary dielectric layer pattern 106a and the hard mask pattern 108a, which may be sequentially stacked, may be formed on the preliminary tunnel oxide layer 102.

Referring to FIG. 5, a silicon nitride layer (not shown) may be formed on the preliminary gate structure 110 and the preliminary tunnel oxide layer 102.

The silicon nitride layer may be anisotropically etched to form a spacer 112 on a sidewall of the preliminary gate structure 110.

The preliminary tunnel oxide layer 102 may be partially removed until an upper surface of the semiconductor substrate 100 between the preliminary gate structures 110 is exposed to form a preliminary tunnel oxide layer pattern 102a.

To facilitate oxidation of the semiconductor substrate 100 at both sides of the preliminary gate structure 110 during a subsequent thermal oxidation process, the exposed surface of the semiconductor substrate 100 may be additionally etched to a depth of about 100 Å.

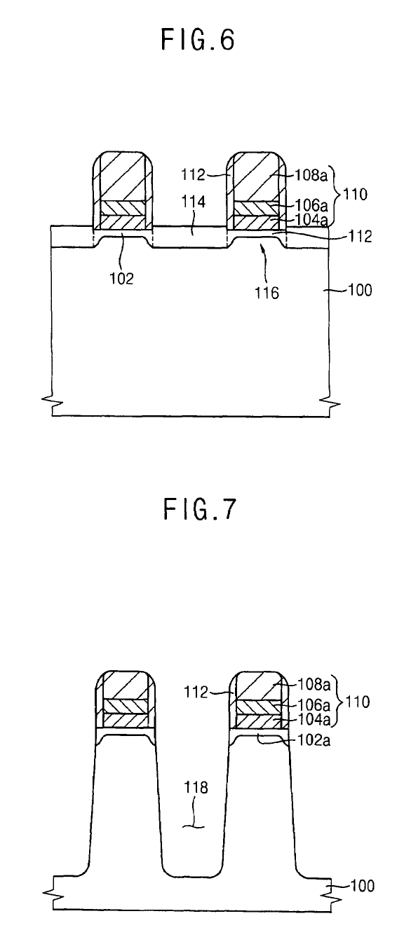

Referring to FIG. 6, the exposed surface of the semiconductor substrate 100 may be selectively thermally oxidized to form a thermal oxide layer 114 on the exposed surface of the semiconductor substrate 100. The thermal oxidation process may be performed by, e.g., a wet thermal oxidation process using H₂O as a reaction gas.

A portion of the semiconductor substrate 100 beneath the thermal oxide layer 114 may be partially exhausted during the thermal oxidation process. As a result, a portion of the semiconductor substrate 100 beneath a central portion of the preliminary gate structure 110 may protrude upward relative to the exhausted portion of the semiconductor substrate 100.

After the thermal oxidation process is completed, an active region formed during a subsequent process may include rounded upper edge portions 125a. Further, the protruded portion of the semiconductor substrate 100 beneath the central portion of the preliminary gate structure 110 may include flat upper central portion 125b. The flat upper central portion 125b may correspond to the active region of the non-volatile memory device.

Furthermore, in cases in which the spacer 112 is formed on the sidewall of the preliminary gate structure 110, the sidewall of the preliminary gate structure 110 is not oxidized during the thermal oxidation process.

Moreover, the flat upper central portion 125b of the active region may serve as an effective tunnel oxide layer pattern of all of the preliminary tunnel oxide layer patterns 102a. In contrast, the relatively thick silicon oxide layer on the rounded upper edge portion of the active region caused by the thermal oxidation process may not serve as the effective tunnel oxide layer patterns. That is, because edges of the preliminary tunnel oxide layer pattern 102a may be oxidized during the thermal oxidation process, a width, along the second direction, of the effective tunnel oxide layer pattern may be narrowed, i.e., slightly narrowed. As a result, in some embodiments of the invention, the width of the effective tunnel oxide layer pattern, along the second direction, may be narrower than a width of the preliminary floating gate electrode 104a, along the second direction.

The relatively narrow width of the effective tunnel oxide layer pattern may result in a decrease in a capacitance of the effective tunnel oxide layer pattern so that such exemplary non-volatile memory devices employing one or more aspects of the invention may have an improved coupling ratio.

Referring to FIG. 7, the thermal oxide layer 114 and the semiconductor substrate 100 may be etched using the preliminary gate structure 110 having the spacer 112 as an etching mask to form an isolation trench 118, thereby defining the active region and the field region of the semiconductor substrate 100. The active region may include the rounded upper edge portion 125a due to the thermal oxidation process.

The hard mask pattern 108a and the spacer 112 on the preliminary gate structure 110 may then be partially removed so that thicknesses of the hard mask pattern 108a and the spacer 112 are reduced.

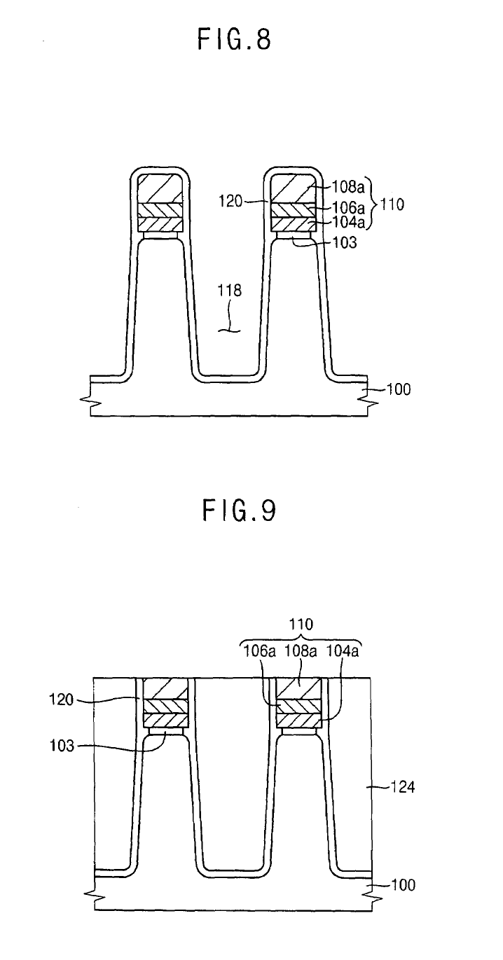

Referring to FIG. 8, the spacer 112 on the sidewall of the preliminary gate structure 110 may be entirely oxidized by a radical oxidation process.

The radical oxidation process may include applying a reaction gas including oxygen and hydrogen, and exciting the reaction gas to form a reaction plasma. The reaction gas may be excited at a power of about 1,000 watts to about 5,000 watts under a pressure of about 1 mTorr to about 10 mTorr.

Further, oxygen radicals in the reaction plasma may have a kinetic energy greater than that of oxygen gas, and an activation energy lower than that of oxygen gas. Thus, the radical oxidation process may be carried out at a temperature of about 350° C. to about 650° C., which is lower than about 800° C. at which a conventional wet or dry oxidation process is performed. Furthermore, an oxide layer formed by the radical oxidation process may have a thickness smaller than that of an oxide layer formed by the wet oxidation process.

The reaction plasma may be directly formed in a reaction chamber. Particularly, in some cases, the reaction gas may be introduced into the reaction chamber. A radio frequency (RF) power may be applied to the reaction gas to form the reaction plasma. In other cases, the reaction plasma may be provided from a remote plasma generator connected to the reaction chamber. Particularly, in some cases, microwave energy may be applied to the reaction gas supplied to the remote plasma generator to form the reaction plasma.

The reaction gas may further include an inert gas as an ignition gas for forming and maintaining the reaction plasma, e.g., argon, nitrogen, helium, etc.

The radical oxidation process may oxidize exposed surface(s) of the hard mask pattern 108a, which may include silicon nitride, exposed surface(s) of the semiconductor substrate 100, and exposed surface(s) of the spacer 112, which may include silicon nitride. Therefore, after performing the radical oxidation process, a silicon oxide layer 120 may be formed on an upper surface of the hard mask pattern 108a and a sidewall of the isolation trench 118.

Particularly, the silicon on the sidewall of the isolation trench 118 may be exhausted due to oxidation of the sidewall of the isolation trench 118 and a width of the active region may be narrowed, i.e., slightly narrowed. Further, the flat upper central portion 125b of the active region may be defined as the effective tunnel oxide layer pattern 103 that may function as an effective tunnel oxide layer.

Referring to FIG. 9, an insulation layer (not shown) may be formed on the preliminary gate structure 110 and may fill up the isolation trench 118. The insulation layer may include a material having a good gap-filling characteristic. Examples of the material that may be used for the insulation layer may include USG, HDP oxide, etc.

The insulation layer may then be removed until an upper surface of the hard mask pattern 108a is exposed to form a preliminary isolation layer 124. Removal of the insulation layer may be carried out by, e.g., a chemical mechanical polishing (CMP) process.

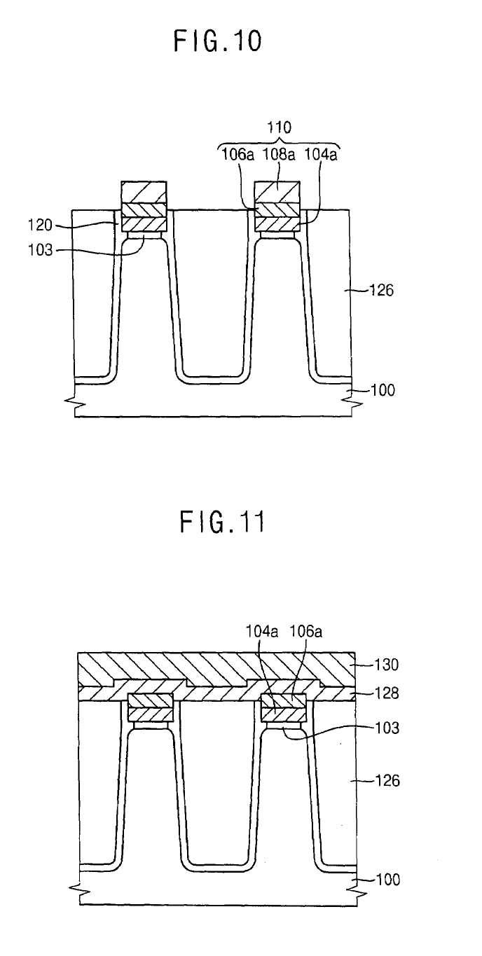

Referring to FIG. 10, the preliminary isolation layer 124 may be partially etched until a sidewall of the preliminary dielectric layer pattern 106a is partially exposed to form the insulation layer 126.

The preliminary isolation layer 124 may be etched by, e.g., a wet etching process, a dry etching process, etc. In some embodiments of the invention, to decrease surface damage of the layers due to plasma, the preliminary isolation layer 124 may be etched by the wet etching process.

Further, in some embodiments of the invention, a sidewall of the preliminary floating gate electrode 104a may not be exposed as a result of the etching process.

Referring to FIG. 11, the hard mask pattern 108a may then be removed. The hard mask pattern 108a may be removed by, e.g., a wet etching process.

A metal nitride layer 128 for the control gate electrode 128a may be formed on the preliminary dielectric layer pattern 106a and the isolation layer 126. In some embodiments of the invention, the metal nitride layer 128 may have a work function of at least about 4.5 eV. Further, the metal nitride layer 128 may not change a dielectric constant of the preliminary dielectric layer pattern 106a. The metal nitride layer 128 may include, e.g., tantalum nitride, titanium nitride, etc.

When the metal nitride layer having a work function higher than a predetermined level, e.g., about 4.5 eV, is used for the control gate electrode, an energy barrier between the control gate electrode and the dielectric layer pattern becomes higher. Thus, the backward transmission of the electrons from the control gate electrode to the dielectric layer pattern may be decreased.

A polysilicon layer 130 may then be formed on the metal nitride layer 128. The work function of the control gate electrode 128a may be determined in accordance with the metal nitride layer 128 making contact with the preliminary dielectric layer pattern 106a. The polysilicon layer 130 may serve to assist in patterning the metal nitride layer 128 and to protect the control gate electrode 128a.

However, when the polysilicon layer 130 is formed on the metal nitride layer 128, the polysilicon layer 130 may be patterned by a subsequent process to form a polysilicon layer pattern 130a on the control gate electrode. Thus, a parasitic capacitance may be generated due to the polysilicon layer pattern.

Referring to FIGS. 1 and 11, the polysilicon layer 130, the metal nitride layer 128, the preliminary dielectric layer pattern 106a and the preliminary floating gate electrode 104a may be patterned to form the gate structure including the effective tunnel oxide layer pattern 103, the floating gate electrode 104b, the dielectric layer pattern 106b, the control gate electrode 128a and the polysilicon layer pattern 130a, which may be sequentially stacked.

In the preliminary gate structure 10, the floating gate electrode 104b and the dielectric layer pattern 106b may have an isolated shape. The control gate electrode 128a, which may include metal nitride, may have a substantially linear shape extending along the second direction substantially perpendicular to a direction along which the active region may extend.

Impurities may be implanted into the semiconductor substrate 100 at both sides of the gate structure to form the source/drain regions 132. A channel region may be formed between the source/drain regions 132.

In the exemplary embodiments illustrated in FIGS. 1-11, the effective tunnel oxide layer 103 has a width, along the second direction, which is narrower than a width, along the second direction, of the floating gate electrode 104b so that the tunnel oxide layer 103 may have a low capacitance. Further, the isolated dielectric layer pattern having a high dielectric constant may be formed on the floating gate electrode so that the dielectric layer pattern 106b may have a high capacitance. As a result, the coupling ratio of the non-volatile memory device may be increased.

Further, because the non-volatile memory device may have a high coupling ratio, a height of the floating gate electrode 104b may be reduced so that a window margin with respect to programming and erasing data may be ensured.

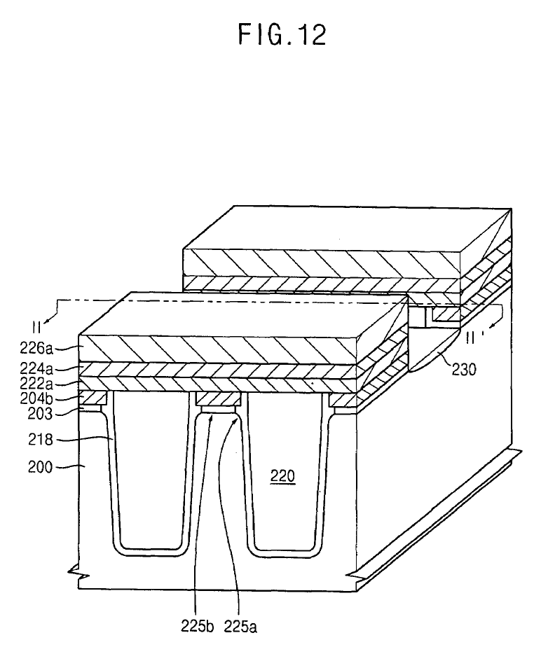

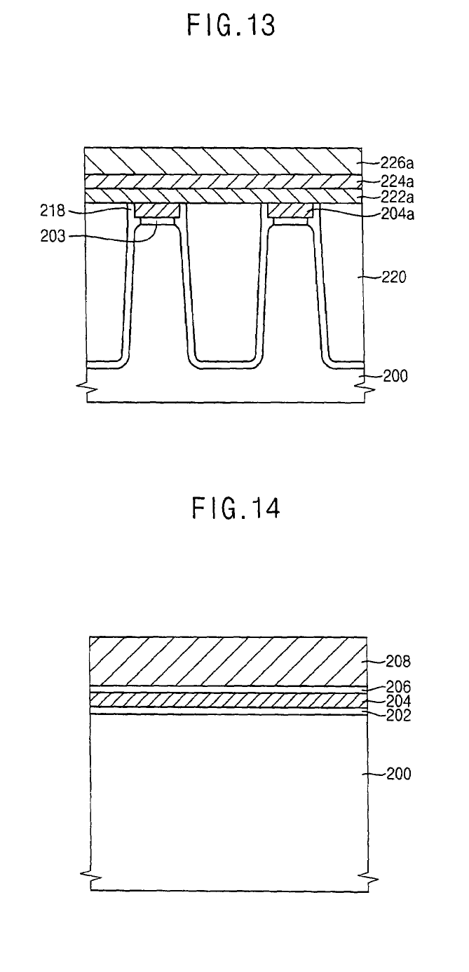

FIG. 12 illustrates a perspective view of a second exemplary embodiment of a non-volatile memory device employing one or more aspects of the present invention; and FIG. 13 illustrates a cross-sectional view of the second exemplary embodiment of the non-volatile memory device illustrated in FIG. 12, taken along a line II-II′ in FIG. 12.

The second exemplary embodiment of a non-volatile memory device may include substantially the same elements as those in the first exemplary embodiment illustrated in FIGS. 1 through 11, except for a linear shape of a dielectric pattern that may be substantially perpendicular to the direction along which the active region extends. Thus, any further illustrations and/or description with respect to the same elements are omitted herein for brevity.

Referring to FIGS. 12 and 13, isolation layers 220 may be formed in a semiconductor substrate 200 to define an active region and a field region of the semiconductor substrate 200. The active region and the field region may have substantially linear shapes extending along a first direction that traverses the semiconductor substrate 200. The active region may include a rounded upper edge portion 225a and a flat upper central portion 225b.

An effective tunnel oxide layer 203 may be formed on the flat upper central portion 225b of the active region. A relatively thick oxide layer 218 may be formed on the rounded upper edge portion 225a of the active region. The thick oxide layer 218 may not function as the effective tunnel oxide layer 203. Thus, the effective tunnel oxide layer 203 may have a relatively small effective area.

A floating gate electrode 204b may be formed on the effective tunnel oxide layer 203. The floating gate electrode 204b may correspond to a split floating gate electrode. The floating gate electrode 204b may have a width, along a second direction substantially perpendicular to the first direction, which is greater than that of the flat upper central portion of the active region. The floating gate electrode 104b may have a thickness of about 150 Å to about 300 Å.

A linear dielectric layer pattern 222a may be formed on the floating gate electrode 204b. The dielectric layer pattern 222a may include metal oxide having a high dielectric constant of no less than about 10.

The dielectric layer pattern 222a may include, e.g., tantalum oxide (Ta₂O₅), titanium oxide (TiO₂), hafnium oxide (HfO₂), zirconium oxide (ZrO₂), hafnium silicate (HfSiₓO_{y}), zirconium silicate (ZrSiₓO_{y}), hafnium nitride silicate (HfSiₓO_{y}N_{z}), zirconium nitride silicate (ZrSiₓO_{y}N_{z}), aluminum oxide (Al₂O₃), aluminum nitride oxide (AlₓO_{y}N_{z}), hafnium aluminate (HfAlₓO_{y}), yttrium oxide (Y₂O₃), niobium oxide (Nb₂O₅), cesium oxide (CeO₂), indium oxide (InO₃), lanthanum oxide (LaO₂), strontium titanium oxide (SrTiO₃), lead titanium oxide (PbTiO₃), strontium ruthenium oxide (SrRuO₃), calcium ruthenium oxide (CaRuO₃), etc. These may be used alone or in combination.

A control gate electrode 224a may be formed on the dielectric layer pattern 222a. The control gate electrode 224a may have a substantially linear shape substantially the same as that of the dielectric layer pattern 222a. The control gate electrode 224a may include a metal nitride layer pattern having a high work function of about 4.6 eV to about 5.2 eV. The metal nitride layer pattern may include tantalum nitride, titanium nitride, etc. These may be used alone or in combination.

A polysilicon layer pattern 226a may be formed on the control gate electrode 224a including the metal nitride layer pattern.

Source/drain regions 230 may be formed in the semiconductor substrate 200 between the control gate electrodes 224a.

In the second exemplary embodiment, the dielectric layer pattern has a substantially linear shape extending along a direction substantially perpendicular to the first direction along which the active region extends. Therefore, the non-volatile memory device may be manufactured by relatively simple processes.

An exemplary method of manufacturing the non-volatile memory device in FIGS. 12 and 13 is described below.

FIGS. illustrate cross-sectional views of stages in a method of manufacturing the non-volatile memory device illustrated in FIGS. 12 and 13.

Referring to FIG. 14, a preliminary tunnel oxide layer 202, a floating gate layer 204, a buffer oxide layer 206 and a hard mask layer 208 may be sequentially formed on the semiconductor substrate 200, e.g., single crystalline silicon substrate.

The preliminary tunnel oxide layer 202 may be formed by, e.g., thermally oxidizing the semiconductor substrate 200.

The floating gate layer 204 may then be formed. For example, polysilicon for keeping and discharging electrons may be deposited on the preliminary tunnel oxide layer 202 to form the floating gate layer 204. Here, the floating gate layer 204 may have a thickness substantially the same as that of a floating gate electrode to be formed. When the floating gate layer 204 has a thickness of less than about 150 Å, the floating gate layer 204 may have poor electron retention characteristics and/or patterning the floating gate layer 204 may be very difficult. In contrast, when the floating gate layer 204 has a thickness of more than about 300 Å, a parasitic capacitance between the adjacent floating gate electrodes may be increased. Thus, in some embodiments of the invention, the floating gate layer 204 may have a thickness of about 150 Å to about 300 Å.

The buffer oxide layer 206 may function to reduce stresses generated in forming the hard mask layer 208. The buffer oxide layer 206 may be formed by, e.g., thermally oxidizing the floating gate layer 204.

Silicon nitride may be deposited on the buffer oxide layer 206 by, e.g., a CVD process, to form the hard mask layer 208.

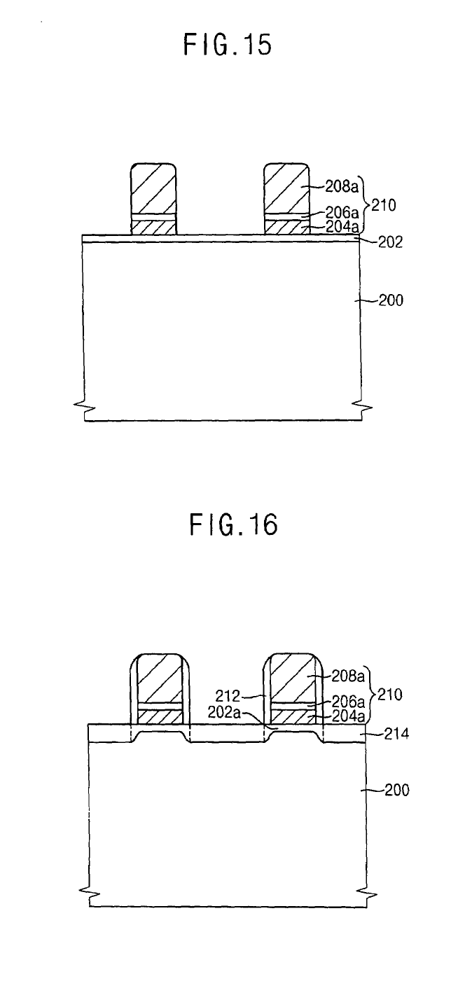

Referring to FIG. 15, the hard mask layer 208 may be patterned by a photolithography method using a photoresist pattern (not shown) process to form a hard mask pattern 208a. The photoresist pattern may then be removed by, e.g., an ashing process and/or a stripping process.

The buffer oxide layer 206 and the floating gate layer 204 may be etched using the hard mask pattern 208a as an etching mask to form a buffer oxide layer pattern 206a and a preliminary floating gate electrode 204a, respectively.

After the etching process is completed, a linear preliminary gate structure 210 including the preliminary floating gate electrode 204a, the buffer oxide layer pattern 206a and the hard mask pattern 208a, which may be sequentially stacked, may be formed on the preliminary tunnel oxide layer 202.

Referring to FIG. 16, a silicon nitride layer (not shown) may be formed on the preliminary gate structure 210 and the preliminary tunnel oxide layer 202. The silicon nitride layer may be anisotropically etched to form a spacer 212 on a sidewall of the preliminary gate structure 210.

The preliminary tunnel oxide layer 202 may be partially removed until an upper surface of the semiconductor substrate 200 between the preliminary gate structures 210 is exposed to form a preliminary tunnel oxide layer pattern 202a. The exposed surface of the semiconductor substrate 200 may be etched by a depth of about 100 Å.

The exposed surface of the semiconductor substrate 200 may be selectively thermally oxidized to form a thermal oxide layer 214 on the exposed surface of the semiconductor substrate 200. The thermal oxidation process may be performed by, e.g., a wet thermal oxidation process using H₂O as a reaction gas.

A portion of the semiconductor substrate 200 beneath the thermal oxide layer 124 may be partially exhausted during the thermal oxidation process. As a result, another portion of the semiconductor substrate 200 beneath a central portion of the preliminary gate structure 210 may protrude relative to the exhausted portion of the semiconductor substrate 200. Further, the protruded portion of the semiconductor substrate 200 beneath the central portion of the preliminary gate structure 210 may include the flat upper central portion 225b.

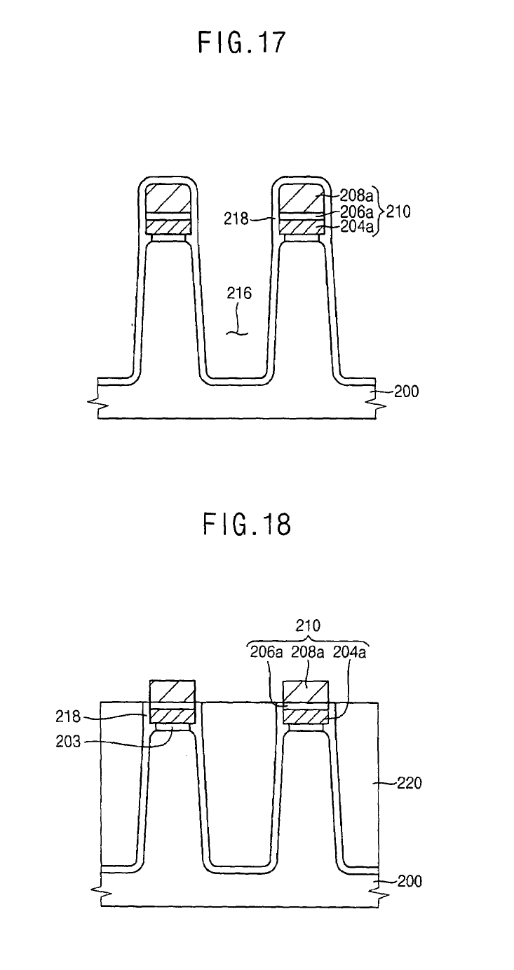

Referring to FIG. 17, the thermal oxide layer 214 and the semiconductor substrate 200 may be etched using the preliminary gate structure 210 having the spacer 212 as an etching mask to form an isolation trench 216, thereby defining the active region and the field region of the semiconductor substrate 120. After forming the spacer 212, the active region may have rounded upper edge portion(s) 225a due to the thermal oxidation process.

The spacer 212 on the sidewall of the preliminary gate structure 210 may be entirely oxidized by a radical oxidation process. The radical oxidation process may oxidize an upper face of the hard mask pattern 208a and the sidewall of the isolation trench 216 to form an oxide layer 218.

In some embodiments of the invention, silicon in the sidewall of the isolation trench 216 may be exhausted due to the oxidation of the sidewall of the isolation trench 216 and a width of the active region may be narrowed, i.e., slightly narrowed. Further, the flat upper central portion 225b of the active region may be defined as the effective tunnel oxide layer pattern 203, which may function as an effective tunnel oxide layer.

Referring to FIG. 18, an insulation layer (not shown) may be formed on the preliminary gate structure 210 and may fill up the isolation trench 216. The insulation layer may include a material having a good gap-filling characteristic, e.g., silicon oxide.

The insulation layer may then be removed until an upper surface of the hard mask pattern 208a is exposed to form a preliminary isolation layer (not shown). Removal of the insulation layer may be carried out by a chemical mechanical polishing (CMP) process.

The preliminary isolation layer may be partially etched until a sidewall of the hard mask pattern 208a is entirely exposed. The preliminary isolation layer may be etched by, e.g., a wet etching process, a dry etching process, etc. In some embodiments of the invention, to decrease surface damage of the layers due to plasma, the preliminary isolation layer may be etched by a wet etching process.

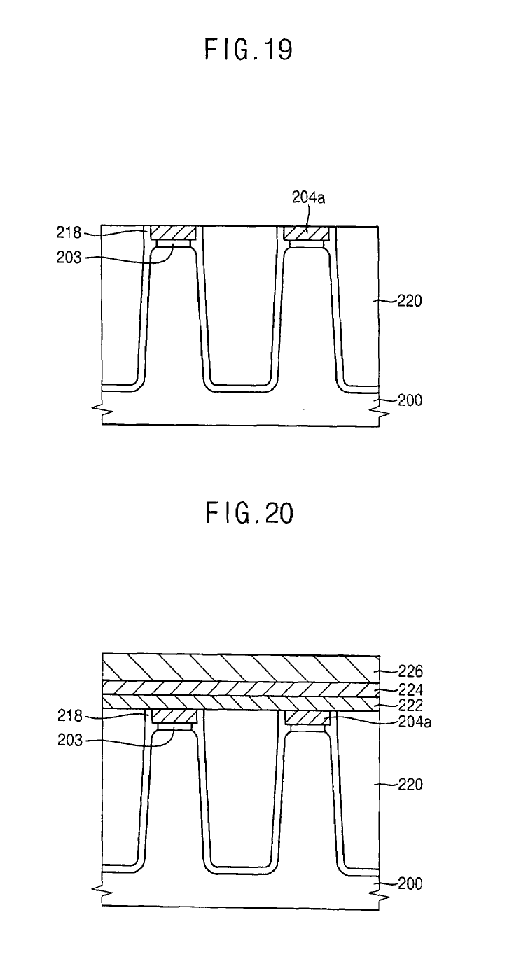

Referring to FIG. 19, the hard mask pattern 208a may then be removed. The hard mask pattern 208a may be removed by, e.g., a wet etching process.

The buffer oxide layer 206a remaining on the preliminary floating gate electrode 204a may be removed to form the isolation layer 220. Here, the preliminary isolation layer may be removed simultaneously with the buffer oxide layer 206a. The isolation layer 220 may be positioned between the preliminary floating gate electrodes 204a. Further, an upper surface of the preliminary floating gate electrode 204a may be partially exposed through the isolation layer 220.

Referring to FIG. 20, metal oxide having a high dielectric constant of no less than about ten (10) may be deposited on the preliminary floating gate electrode 204a and the isolation layer 220 to form a dielectric layer 222.

In some embodiments of the invention, e.g., the second exemplary embodiment, the metal oxide may include hafnium oxide, hafnium aluminate having a dielectric constant of about twenty (20), etc. The hafnium oxide and the hafnium aluminate may be deposited by a CVD process, an ALD process, etc.

A metal nitride layer 224 may be formed on the dielectric layer 222. The metal nitride layer 224 may have a work function of at least about 4.5 eV. Further, the metal nitride layer 224 may not change a dielectric constant of the dielectric layer 222. The metal nitride layer 224 may include, e.g., tantalum nitride, titanium nitride, etc.

A polysilicon layer 226 may be formed on the metal nitride layer 224.

Referring to FIGS. 12 and 20, the polysilicon layer 226, the metal nitride layer 224, the dielectric layer 222 and the preliminary floating gate electrode 204a may be patterned to form the gate structure including the effective tunnel oxide layer pattern 203, the floating gate electrode 204b, the dielectric layer pattern 222a, the control gate electrode 224a and the polysilicon layer pattern 226a, which may be sequentially stacked. In the gate structure, the dielectric layer pattern 222a, the control gate electrode 224a and the polysilicon layer pattern 226a may have a substantially linear shape extending along the second direction substantially perpendicular to the direction along which the active region extends.

Impurities may be implanted into the semiconductor substrate 200 at both sides of the gate structure to form the source/drain regions 230. A channel region may be formed between the source/drain regions 230.

According to the second exemplary embodiment, because the dielectric layer pattern may be formed by performing a patterning process only once, the non-volatile memory device may be manufactured by simpler processes. Further, a coupling ratio of the non-volatile memory device may be increased. Furthermore, a window margin with respect to programming and erasing data may be ensured.

According to one or more aspects of the present invention, a highly integrated non-volatile memory device may have a high coupling ratio and a sufficient window margin with respect to programming and erasing the data.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A non-volatile memory device, comprising:
a substrate having a field region and an active region including a rounded upper edge portion and a flat upper central portion;
an effective tunnel oxide layer on the flat upper central portion of the active region;
a split floating gate electrode on the effective tunnel oxide layer, the floating gate electrode having a width greater than a width of the effective tunnel oxide layer;
a dielectric layer pattern on the floating gate electrode, the dielectric layer pattern including metal oxide; and
a control gate electrode on the dielectric layer pattern.

2. The non-volatile memory device as claimed in claim 1, wherein the dielectric layer pattern is a split dielectric layer pattern having a shape corresponding to a shape of the floating gate electrode.

3. The non-volatile memory device as claimed in claim 1, wherein the dielectric layer pattern is a linear dielectric layer pattern extending on the field region beyond the rounded upper edge portion of the active region.

4. The non-volatile memory device as claimed in claim 1, wherein the dielectric layer pattern includes at least one of tantalum oxide (Ta₂O₅), titanium oxide (TiO₂), hafnium oxide (HfO₂), zirconium oxide (ZrO₂), hafnium silicate (HfSiₓO_{y}), zirconium silicate (ZrSiₓO_{y}), hafnium nitride silicate (HfSiₓO_{y}N_{z}), zirconium nitride silicate (ZrSiₓO_{y}N_{z}), aluminum oxide (Al₂O₃), aluminum nitride oxide (AlₓO_{y}N_{z}), hafnium aluminate (HfAlₓO_{y}), yttrium oxide (Y₂O₃), niobium oxide (Nb₂O₅), cesium oxide (CeO₂), indium oxide (InO₃), lanthanum oxide (LaO₂), strontium titanium oxide (SrTiO₃), lead titanium oxide (PbTiO₃), strontium ruthenium oxide (SrRuO₃) and calcium ruthenium oxide (CaRuO₃).

5. The non-volatile memory device as claimed in claim 1, wherein the floating gate electrode includes polysilicon.

6. The non-volatile memory device as claimed in claim 1, wherein the control gate electrode includes a metal nitride layer pattern.

7. The non-volatile memory device as claimed in claim 6, further comprising a polysilicon layer pattern on the metal nitride layer pattern.

8. The non-volatile memory device as claimed in claim 1, wherein the floating gate electrode has a thickness of about 150 Å to about 300 Å.

9. A method of manufacturing a non-volatile memory device, comprising:
forming a preliminary gate structure on a substrate, the preliminary gate structure including a preliminary tunnel oxide layer, a preliminary floating gate electrode and a preliminary dielectric layer pattern including metal oxide, which are sequentially stacked;
selectively oxidizing surfaces of the substrate at sides of the preliminary gate structure to form an effective tunnel oxide layer including the preliminary tunnel oxide layer;
forming trench isolation layers in the substrate at the sides of the preliminary gate structure to define a field region and an active region of the substrate;
forming a conductive layer on the preliminary gate structure; and
patterning the preliminary floating gate electrode, the preliminary dielectric layer pattern and the conductive layer to form a floating gate electrode, a dielectric layer pattern and a control gate electrode.

10. The method as claimed in claim 9, wherein the preliminary dielectric layer pattern includes at least one of tantalum oxide (Ta₂O₅), titanium oxide (TiO₂), hafnium oxide (HfO₂), zirconium oxide (ZrO₂), hafnium silicate (HfSiₓO_{y}), zirconium silicate (ZrSiₓO_{y}), hafnium nitride silicate (HfSiₓO_{y}N_{z}), zirconium nitride silicate (ZrSiₓO_{y}N_{z}), aluminum oxide (Al₂O₃), aluminum nitride oxide (AlₓO_{y}N_{z}), hafnium aluminate (HfAlₓO_{y}), yttrium oxide (Y₂O₃), niobium oxide (Nb₂O₅), cesium oxide (CeO₂), indium oxide (InO₃), lanthanum oxide (LaO₂), strontium titanium oxide (SrTiO₃), lead titanium oxide (PbTiO₃), strontium ruthenium oxide (SrRuO₃) and calcium ruthenium oxide (CaRuO₃).

11. The method as claimed in claim 9, wherein selectively oxidizing surfaces of the substrate at sides of the preliminary gate structure comprises selectively oxidizing surfaces of the substrate using a wet oxidation process.

12. The method as claimed in claim 9, further comprising forming a hard mask pattern on the preliminary dielectric layer pattern, the hard mask pattern being used for patterning the preliminary gate structure and including silicon nitride.

13. The method as claimed in claim 12, further comprising forming a spacer including silicon nitride on sidewalls of the preliminary gate structure and the hard mask pattern.

14. The method as claimed in claim 13, wherein forming the trench isolation layer comprises;
etching the substrate using the preliminary gate structure as an etching mask to form an isolation trench;
filling the isolation trench with a preliminary isolation layer;
partially removing the preliminary isolation layer until a sidewall of the preliminary dielectric layer pattern is partially exposed to form the trench isolation layer; and
removing the hard mask pattern to expose an upper face of the preliminary dielectric layer pattern.

15. The method as claimed in claim 14, wherein before forming the preliminary isolation layer, the method comprises oxidizing the spacer on the sidewalls of the preliminary gate structure and the hard mask pattern to convert the silicon nitride in the spacer into oxide.

16. The method as claimed in claim 15, wherein the spacer is oxidized using a radical oxidation process.

17. The method as claimed in claim 9, wherein selectively oxidizing surface of the substrate comprises selectively oxidizing surfaces of the substrate at opposing sides of the preliminary gate structure.

18. A method of manufacturing a non-volatile memory device, comprising:
forming a preliminary gate structure on a substrate, the preliminary gate structure including a preliminary tunnel oxide layer and a preliminary floating gate electrode sequentially stacked;
selectively oxidizing surfaces of the substrate at both sides of the preliminary gate structure to form an effective tunnel oxide layer including the preliminary tunnel oxide layer;
forming trench isolation layers in the substrate at the both sides of the preliminary gate structure to define a field region and an active region of the substrate, the active region having a flat upper central portion on which the effective tunnel oxide layer is positioned;
sequentially forming a dielectric layer including metal oxide and a control gate layer on the preliminary gate structure; and
patterning the preliminary floating gate electrode, the dielectric layer and the control gate layer to form a split floating gate electrode, a dielectric layer pattern and a control gate electrode.

19. The method as claimed in claim 18, further comprising sequentially forming a buffer oxide layer pattern and a hard mask pattern on the preliminary dielectric layer pattern, the buffer oxide layer pattern and hard mask pattern being used for patterning the preliminary gate structure.

20. The method as claimed in claim 19, wherein forming the trench isolation layer comprises;
etching the substrate using the preliminary gate structure as an etching mask to form an isolation trench;
filling the isolation trench with a preliminary isolation layer;
partially removing the preliminary isolation layer to form the trench isolation layer, the trench isolation layer having an upper surface that is positioned on a plane on which an upper surface of the preliminary floating gate electrode is placed; and
removing the hard mask pattern and the buffer oxide layer pattern to expose an upper face of the preliminary floating gate electrode.
